(19) United States
(12) Patent Application Publication
(10) Pub. No.: US 2025/0318409 A1
(43) Pub. Date: Oct. 9, 2025

(54) DISPLAY DEVICE, ELECTRONIC DEVICE AND METHOD FOR MANUFACTURING THE DISPLAY DEVICE

(71) Applicant: Samsung Display Co., LTD., Yongin-si (KR)

(72) Inventors: DONGWOOK LEE, Yongin-si (KR); Young-Mo KOO, Yongin-si (KR)

(21) Appl. No.: 19/062,833

(22) Filed: Feb. 25, 2025

(30) Foreign Application Priority Data
Apr. 5, 2024 (KR) 10-2024-0046733
Dec. 24, 2024 (KR) 10-2024-0195492

(51) Int. Cl. H10K 59/80; H10K 50/16; H10K 59/12; H10K 59/38

(52) U.S. Cl. CPC H10K 59/873; H10K 50/16; H10K 59/1201; H10K 59/38

(57) ABSTRACT

A display device includes, a partition wall having a first, second and third opening, a first, second, and third light emitting layer in the first, second, and third openings, respectively, and an encapsulation layer on the first light emitting layer, the second light emitting layer, and the third light emitting layer, wherein the first light emitting layer and the second light emitting layer each include a quantum dot, the third light emitting layer includes an organic material, the encapsulation layer includes a first inorganic layer, a second inorganic layer on the first inorganic layer, and an organic layer between the first inorganic layer and the second inorganic layer, wherein the organic layer includes a first organic sub-layer including polyacrylic acid, and a second organic sub-layer including a monomer, and the first organic sub-layer overlaps the first opening and the second opening and is spaced from the third opening.

### CROSS-REFERENCE TO RELATED APPLICATION

The present application claims priority to and the benefit of Korean Patent Application No. 10-2024-0046733, filed on Apr. 5, 2024, in the Korean Intellectual Property Office, and Korean Patent Application No. 10-2024-0195492, filed on Dec. 24, 2024, in the Korean Intellectual Property Office, the entire content of each of which is incorporated herein by reference.

### BACKGROUND

### 1. Field

Embodiments of the present disclosure relates to a display device, an electronic device and a method of manufacturing the display device.

### 2. Description of the Related Art

A light emitting element may form an exciton by combining a hole supplied from an anode and an electron supplied from a cathode within a light emitting layer formed between the anode and cathode, and may emits light if (e.g., when) this exciton is stabilized (i.e., when it relaxes from an excited state).

Light emitting elements, e.g., light emitting diodes (LEDs) may offer several (various) enhancements and/or advantages such as relatively wide viewing angle, fast response speed, thinness, and/or low power consumption. As a result, they may be widely applied to various electrical and electronic devices, such as televisions, monitors, and/or mobile phones.

### SUMMARY

Aspects of one or more embodiments of the present disclosure are directed toward a display device and its manufacturing method that have improved lifespan and efficiency by patterning the organic layer of the encapsulation layer of the light emitting element.

Additional aspects will be set forth in part in the description which follows and, in part, will be apparent from the description, or may be learned by practice of the presented embodiments of the disclosure.

A display device according to one or more embodiments of the present disclosure includes a substrate, a transistor on the substrate, a first electrode on the transistor, a partition wall on the first electrode and having a first opening, a second opening, and a third opening, a first light emitting layer in the first opening, a second light emitting layer in the second opening, a third light emitting layer in the third opening, an encapsulation layer on the first light emitting layer, the second light emitting layer, and the third light emitting layer, wherein the first light emitting layer and the second light emitting layer each include a quantum dot, the third light emitting layer includes an organic material, the encapsulation layer includes a first inorganic layer, a second inorganic layer on the first inorganic layer, and an organic layer between the first inorganic layer and the second inorganic layer, wherein the organic layer includes a first organic sub-layer including polyacrylic acid, and a second organic sub-layer including a monomer, and the first organic sub-layer overlaps the first opening and the second opening and is spaced and/or apart (e.g., spaced apart or separated) from the third opening.

In one or more embodiments, the first organic sub-layer may be continuously arranged over the first opening and the second opening.

In one or more embodiments, the first organic sub-layer may include two organic sub-layers spaced and/or apart (e.g., spaced apart or separated) from each other on (e.g., on and into) the first opening and the second opening.

In one or more embodiments, the surface of the first organic sub-layer may include a curved surface.

In one or more embodiments, a refractive index of the first organic sub-layer may be greater than a refractive index of the second organic sub-layer.

In one or more embodiments, the difference between the refractive index of the first organic sub-layer and the refractive index of the second organic sub-layer may be 0.15 or greater than 0.15.

In one or more embodiments, a first hole injection layer, a first hole transport layer, and a first electron transport layer may be in the first opening, a second hole injection layer, a second hole transport layer, and a second electron transport layer may be in the second opening, and a third hole injection layer, a third hole transport layer, and a third electron transport layer may be in the third opening.

In one or more embodiments, the first light emitting layer may include a red quantum dot (e.g., red quantum dots), the second light emitting layer may include a green quantum dot (e.g., green quantum dots), and the third light emitting layer may include a blue organic material (e.g., blue organic materials).

In one or more embodiments, the first electron transport layer and the second electron transport layer may include (e.g., formed by or be) a compound represented by the following Chemical Formula 1:

ZnMO Chemical Formula 1

In Chemical Formula 1, M may be Mg, Ca, Zr, W, Li, Ti, Y, Al, and/or a (e.g., any suitable) combination thereof.

In one or more embodiments, the first opening and the second opening may further include a metal oxide layer.

In one or more embodiments, the metal oxide layer may include ZnO.

In one or more embodiments, the substrate may include a red light emitting region to emit red light, a green light emitting region to emit green light, and a blue light emitting region to emit blue light, and wherein the first inorganic layer and the second inorganic layer may each form a (substantially) continuous layer over the red light emitting region, the green light emitting region, and the blue light emitting region.

In one or more embodiments, the monomer may include at least one of dodecyl methacrylate, trimethylolpropane triacrylate, or trimethylbenzoyl diphenyl phosphine oxide.

In one or more embodiments, the first organic sub-layer and the second organic sub-layer may be adjacent to each other without any empty space therebetween.

A method of manufacturing a display device according to one or more embodiments of the present disclosure includes forming a first electrode on a substrate, patterning a partition wall on the first electrode to form a first opening, a second opening, and a third opening, printing a light emitting layer in the first opening, the second opening, and the third opening, depositing a second electrode on the light emitting element, depositing a first inorganic layer on the second electrode, coating an organic layer on the first inorganic layer, and depositing a second inorganic layer on the organic layer, wherein the light emitting layer in each of the first opening and the second opening includes a quantum dot, the light emitting layer in the third opening includes an organic light emitting material, the organic layer includes a first organic sub-layer including polyacrylic acid and a second organic sub-layer including a monomer, and the first organic sub-layer is on the first opening and the second opening and is spaced and/or apart (e.g., spaced apart or separated) from the third opening.

In one or more embodiments, the step (e.g., act or task) of coating the organic layer on the first inorganic layer may include concurrently (e.g., simultaneously) printing the polyacrylic acid and the monomer.

In one or more embodiments, the step (e.g., act or task) of coating an organic layer on the first inorganic layer may include printing the monomer after printing the polyacrylic acid.

In one or more embodiments, printing the polyacrylic acid may include forming the surface of the polyacrylic acid to include a curved surface.

An electronic device according to one or more embodiments of the present disclosure includes a memory, a processor to execute an application stored in the memory and a display device comprising a display module to output video information provided by the application, wherein the display device comprising a substrate, a transistor on the substrate, a first electrode on the transistor, a partition wall on the first electrode and having a first opening, a second opening, and a third opening, a first light emitting layer in the first opening, a second light emitting layer in the second opening, a third light emitting layer in the third opening and an encapsulation layer on the first light emitting layer, the second light emitting layer, and the third light emitting layer, wherein, the first light emitting layer and the second light emitting layer each comprise a quantum dot, the third light emitting layer comprises an organic material, the encapsulation layer comprises a first inorganic layer, a second inorganic layer on the first inorganic layer, and an organic layer between the first inorganic layer and the second inorganic layer, and wherein, the organic layer comprises a first organic sub-layer comprising polyacrylic acid, and a second organic sub-layer comprising a monomer, and the first organic sub-layer overlaps the first opening and the second opening and is spaced and/or apart (e.g., spaced apart or separated) from the third opening.

In one or more embodiments, the surface of the first organic sub-layer may include a curved surface.

According to one or more embodiments of the present disclosure, polyacrylic acid is printed on the red and green light emitting layers containing quantum dots, and a monomer is printed on the blue light emitting layer containing an organic light emitting material to pattern the organic layer of the encapsulation layer, thereby preventing or reducing performance degradation of the quantum dots. By preventing or reducing a decrease in the lifespan of the light emitting material, the lifespan and efficiency of the light emitting element can be improved.

### BRIEF DESCRIPTION OF THE DRAWINGS

The accompanying drawings are included to provide a further understanding of the present disclosure, and re incorporated in and constitute a part of this specification. The drawings illustrate example embodiments of the present disclosure and, together with the description, serves to explain principles of present disclosure. In the drawings:

FIG. 1 and FIG. 2 are each a schematic perspective view of an electronic device according to one or more embodiments of the present disclosure.

FIG. 3 is a perspective view of a display device according to one or more embodiments of the present disclosure.

FIG. 4 to FIG. 9 are each a cross-sectional view of a display device according to one or more embodiments of the present disclosure.

FIG. 10 and FIG. 11 are each a flowchart of a manufacturing process of a display device according to one or more embodiments of the present disclosure.

FIG. 12 is a table briefly showing the structures of comparative examples and examples for measuring the effect of improving trap density by polyacrylic acid treatment.

FIG. 13 is a graph of the effect of improving trap density by polyacrylic acid treatment.

FIG. 14 is a table showing that the efficiency of a light emitting element containing quantum dots increases by polyacrylic acid treatment.

FIG. 15 is a table showing the characteristics when polyacrylic acid is printed on the inorganic layer of the encapsulation layer.

FIG. 16 is a block diagram of an electronic device according to one or more embodiments of the present disclosure.

FIG. 17 shows schematic diagrams of electronic devices according to various embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

In order to clearly explain the present disclosure, parts that are not relevant to the description may be omitted. Unless otherwise noted, like reference numerals denote like elements throughout the attached drawings and the written description, and thus, duplicative descriptions thereof may not be provided.

In the drawings, the relative sizes of elements, layers, and regions may be exaggerated for clarity. For example, the size and thickness of each component shown in the drawings may be arbitrarily shown for convenience of explanation, so the present disclosure is not necessarily limited to that which is shown. In the drawing, the thickness may be enlarged to clearly express various layers and regions. And in the drawings, for convenience of explanation, the thicknesses of some layers and regions may be exaggerated.

Additionally, when a part of a layer, membrane, region, or plate is said to be “above” or “on” another part, this includes not only cases where it is “directly above” another part, but also cases where there is another part in between. For example, it will be understood that when an element, such as an area, layer, film, region or portion, is referred to as being “on,” “connected to,” or “above” another element, it can be directly on, connected to, or above the other element, or one or more intervening elements may be present. In contrast, when an element is referred to as being “directly on” another element, there are no intervening elements present. In addition, being “above” or “on” a reference part means being disposed above or below the reference part, and does not necessarily mean being disposed “above” or “on” it in the direction opposite to gravity. In addition, it will also be understood that when an element is referred to as being “between” two elements, it can be the only element between the two elements, or one or more intervening elements may also be present.

It will be further understood that the terms “comprises,” “comprising,” “includes,” “including,” “have,” “having,” “contain,” and “containing” when used in this specification, specify the presence of the stated features, integers, steps, operations, elements, and/or components, but do not preclude the presence or addition of one or more other features, integers, steps, operations, elements, components, and/or groups thereof.

In addition, throughout the specification, when reference is made to “on a plane,” this means when the target part is viewed from above (e.g., in a plan view), and when reference is made to “in a cross-section,” this means when a cross-section of the target portion is cut vertically and viewed from the side.

As used herein, the singular forms “a,” “an” and “the” are intended to include the plural forms as well, unless the context clearly indicates otherwise.

As used herein, “combination thereof” or mixture thereof” may mean a combination or mixture of constituents, a stack, a composite, a copolymer, an alloy, a blend, and/or a reaction product.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

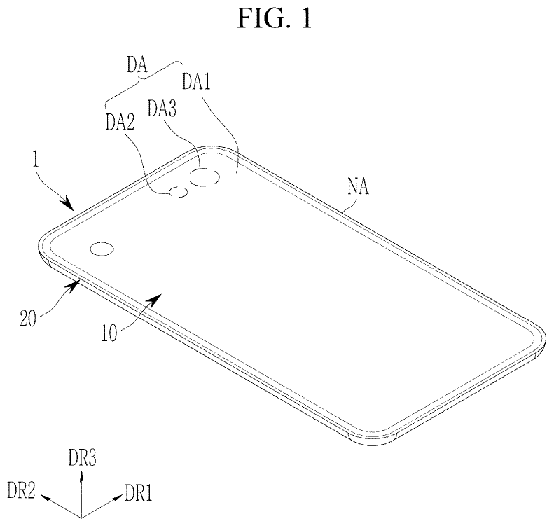

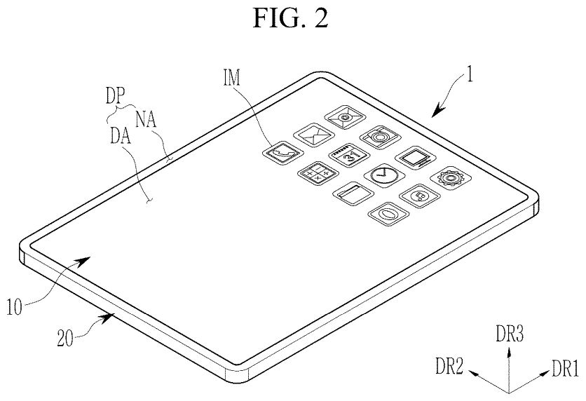

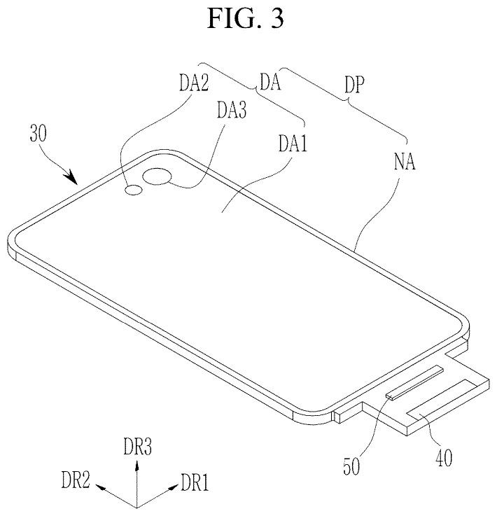

FIGS. 1 and 2 are each a schematic perspective view of an electronic device according to one or more embodiments of the present disclosure. FIG. 3 is a perspective view of a display device according to one or more embodiments of the present disclosure.

Referring to FIGS. 1 and 2, the electronic device 1 may include a display screen capable of displaying images in the third direction DR3, which corresponds to the front in the plane defined by the first direction DR1 and the second direction DR2. The electronic device 1 may be a device that includes displaying images as a function (e.g., main function), such as a smartphone, mobile phone, tablet, multimedia player, game console, monitor, and/or the like.

The electronic device 1 may display an image IM toward the third direction DR3. The image IM may include both dynamic images and still images. FIG. 2 illustrates a plurality of icons as an example of the image IM.

Referring to FIGS. 1 through 3, the electronic device 1 according to one or more embodiments may include a cover window 10, a housing 20, and a display device 30. The cover window 10 may include an insulating panel. For example, the cover window 10 may be made of glass, plastic, or a combination thereof. The front surface of the cover window 10 may define the front of the electronic device 1. The area corresponding to the display screen on the cover window 10 may be optically transparent. The cover window 10 may be positioned over the display device 30 to protect the display device 30 from external impact, and/or the like, and can transmit the image displayed by the display device 30. The cover window 10 may also be considered a component of the display device 30.

The housing 20 may be made of a material with relatively high rigidity. For example, the housing 20 may include glass, plastic, or metal, or it may include a plurality of frames and/or plates made of a combination thereof. The housing 20 may be combined with the cover window 10, and the combined housing 20 and cover window 10 may form the exterior of the electronic device 1 and provide an internal space for the electronic device 1. For example, the housing 20 may form the back and sides of the electronic device 1, and the cover window 10 may form the front of the electronic device 1. Inside the space defined by the cover window 10 and the housing 20, components such as the display device 30 can be located, and components like the display device 30 may be protected from the external environment.

The display device 30 may display images and provide a display screen for the electronic device 1. The display device 30 can be a light-emitting display device such as an organic light-emitting display device, an inorganic light-emitting display device, a quantum dot light-emitting display device, and/or the like.

The electronic device 1 may have various shapes. For instance, as shown in FIG. 1, the electronic device 1 may be a rectangle with rounded corners when viewed from the front (e.g., in a plan view). In addition, the electronic device 1 may have shapes such as a rectangle, square, other polygons, circle, ellipse, and/or the like.

The electronic device 1 and the display device 30 may each include a display area DA and a peripheral area NA. The display area DA and the peripheral area NA shown in FIG. 1 may correspond to the display area DA and the peripheral area NA of the display device 30 shown in FIG. 2. The display area DA is the area where images can be displayed and can correspond to the display screen. The peripheral area NA is an area where images are not displayed. The display area DA can occupy most of the area centered on the front of the electronic device 1, and the peripheral area NA can surround the display area DA.

The display area DA can include a first display area DA1, a second display area DA2, and a third display area DA3. The second display area DA2 and the third display area DA3 can be areas where components such as sensors and cameras are arranged on the back to add various functions to the electronic device 1. The second display area DA2 and the third display area DA3 may correspond to component areas. The second display area DA2 and the third display area DA3 may be surrounded by the first display area DA1. Not only the first display area DA1, but also the second display area DA2 and the third display area DA3 may display images. The position and number of the second display area DA2 and the third display area DA3 can be varied.

To explain the display device 30 in more detail, the display device 30 can provide a display screen on the electronic device 1. The display device 30 can provide the front of the electronic device 1. The display device 30 can have a planar shape similar to that of the electronic device 1.

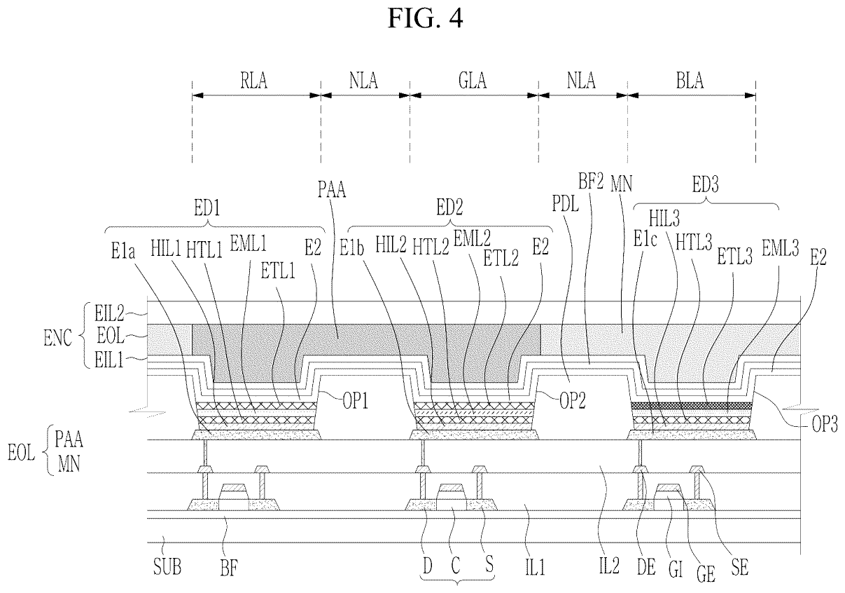

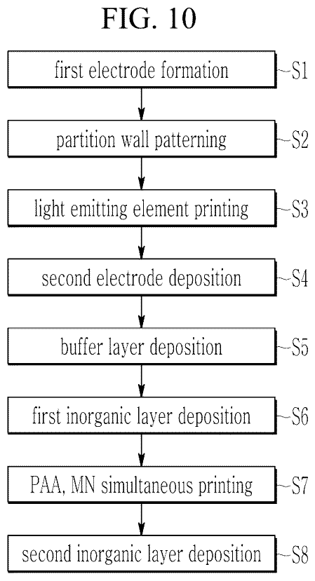

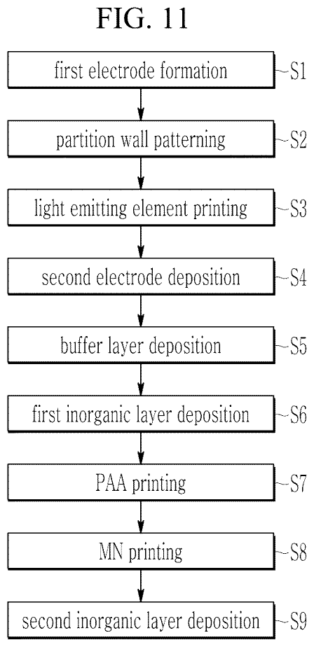

Hereinafter, a display device and a method of manufacturing the display device according to one or more embodiments will be described with reference to FIGS. 4 to 9. FIGS. 4 to 9 are each a cross-sectional view of a display device according to one or more embodiments of the present disclosure, and FIGS. 10 and 11 are each a flowchart of a method of manufacturing a display device according to one or more embodiments of the present disclosure.

Referring to FIG. 4, a display device according to one or more embodiments includes a red light emitting region RLA, a green light emitting region GLA, and a blue light emitting region BLA. A non-light emitting region NLA may be arranged between the red light emitting region RLA, the green light emitting region GLA, and the blue light emitting region BLA. Each light emitting region may correspond to a pixel. For example, the blue light emitting region BLA, the red light emitting region RLA, and the green light emitting region GLA may correspond to blue pixel(s), red pixel(s), and green pixel(s), respectively. The shape and arrangement of each of the red light emitting region RLA, green light emitting region GLA, and blue light emitting region BLA may be modified in one or more suitable ways.

A display device according to one or more embodiments includes a substrate SUB. The substrate SUB may include a flexible material, such as plastic that can bend, fold, or roll, or may include a rigid substrate.

A buffer layer BF may be arranged on the substrate SUB. Depending on the embodiment(s), the buffer layer BF may not be provided. The buffer layer BF may include a silicon nitride SiNₓ a silicon oxide SiOₓ, and/or a silicon oxynitride. The buffer layer BF is arranged between the substrate SUB and the semiconductor layer ACT to block or reduce the likelihood of impurities from the substrate SUB during the crystallization process to form polycrystalline silicon, thereby improving the properties of polycrystalline silicon, and to flatten the substrate SUB to relieve the stress on the semiconductor layer ACT formed on the buffer layer BF.

A semiconductor layer ACT may be arranged on the buffer layer BF (e.g., a semiconductor layer ACT may be arranged on the buffer layer BF at each of the light emitting regions RLA, GLA, and BLA). The semiconductor layer ACT may be made of polycrystalline silicon or an oxide semiconductor. The semiconductor layer ACT includes a channel region C, a source region S, and a drain region D. The source region S and drain region D are respectively arranged on both sides (e.g., opposite sides) of the channel region C. The channel region C is an intrinsic semiconductor that is not doped with impurities, and the source region S and drain region D are impurity semiconductors that are doped with conductive impurities. The semiconductor layer ACT may be made of an oxide semiconductor, in which case a separate protective layer may be added to protect the oxide semiconductor material, which is vulnerable to external environments such as high temperature.

A gate insulating layer GI may be arranged on the semiconductor layer ACT. The gate insulating film GI may be a single layer or a multilayer containing at least one of a silicon nitride SiNₓ, a silicon oxide SiOₓ, and/or a silicon oxynitride.

A gate electrode GE may be arranged on the gate insulating layer GI (e.g., a gate electrode GE may be arranged on the gate insulating layer GI at each of the light emitting regions RLA, GLA, and BLA), and the gate electrode GE can be a multilayer film in which a metal film including one or more of copper Cu, a copper alloy, aluminum Al, an aluminum alloy, molybdenum Mo, and/or a molybdenum alloy is laminated.

An interlayer insulating layer IL1 may be arranged on the gate electrode GE and the gate insulating layer GI. The interlayer insulating layer IL1 may include a silicon nitride SiNₓ, a silicon oxide SiOₓ, and/or a silicon oxynitride (where x is any suitable value, e.g., greater than zero and less than or equal to two). Openings exposing the source region S and drain region D may be arranged in the interlayer insulating layer IL1.

A source electrode SE and a drain electrode DE may be arranged on the interlayer insulating layer IL1 (e.g., a source electrode SE and a drain electrode DE may be arranged on the interlayer insulating layer IL1 at each of the light emitting regions RLA, GLA, and BLA). The source electrode SE and drain electrode DE are respectively connected to the source region S and the drain region D of the semiconductor layer ACT through openings formed in the interlayer insulating layer IL1.

A passivation layer IL2 may be arranged on the interlayer insulating layer IL1, the source electrode SE, and the drain electrode DE. The passivation layer IL2 covers and flattens the interlayer insulating layer IL1, the source electrode SE, and the drain electrode DE, so that the first electrodes E1a, E1b, and E1c can be formed on the passivation layer IL2 without steps (i.e., they can be formed on the flat passivation layer IL2). This passivation layer IL2 may be made of an organic material such as a polyacrylate resin or a polyimide resin, or a laminated film of an organic material and an inorganic material.

First electrodes E1a, E1b, and E1c may be arranged on the passivation layer IL2 (e.g., first electrodes E1a, E1b, and E1c may be arranged on the passivation layer IL2 at the light emitting regions RLA, GLA, and BLA, respectively). The first electrodes E1a, E1b, and E1c are electrically connected to the drain electrode DE through an opening in the passivation layer IL2 (e.g., the first electrodes E1a, E1b, and E1c are each electrically connected to a respective one of the drain electrodes DE through a respective opening in the passivation layer).

A driving transistor including (e.g., consisting of) a gate electrode (GE), a semiconductor layer ACT, a source electrode SE, and a drain electrode DE is connected to the first electrodes E1a, E1b, and E1c, and supplies the driving current to each light emitting element ED1, ED2, and ED3. For example, driving transistors of the light emitting regions RLA, GLA, and BLA each respectively including (e.g., consisting of) a gate electrode (GE), a semiconductor layer ACT, a source electrode SE, and a drain electrode DE are respectively connected to a corresponding one of the first electrodes E1a, E1b, and E1c and supply the driving current to a respective one of the light emitting elements ED1, ED2, and ED3.

In addition to the driving transistor shown in FIG. 4, the display device according to the present embodiment may further include a switching transistor connected to a data line to transmit a data voltage in response to a scan signal, and a switching transistor that is connected to the driving transistor to compensate for the threshold voltage of the driving transistor in response to a scan signal.

A partition wall PDL is arranged on the passivation layer IL2 and the first electrodes E1a, E1b, and E1c. The partition wall PDL may have pixel openings OP1, OP2, and OP3 that overlap the first electrodes E1a, E1b, and E1c and define a light emitting region. The partition wall PDL may contain an organic material such as a polyacrylate resin or a polyimide resin, or a silica-based inorganic material. The pixel openings OP1, OP2, and OP3 may have a planar shape that is almost similar to the first electrodes E1a, E1b, and E1c, and can have a rhombus or octagonal shape similar to a rhombus on a plane (e.g., in a plan view), but are not limited to this, and can have any shape such as a rectangle, a polygon, and/or the like.

According to one or more embodiments, the first light emitting element ED1 can overlap with the red light emitting region RLA, the second light emitting element ED2 can overlap with the green light emitting region GLA, and the third light emitting element ED3 can overlap with the blue light emitting region BLA.

The first light emitting element ED1 includes a first electrode E1a, a first hole injection layer HIL1, a first hole transport layer HTL1, a first light emitting layer EML1, a first electron transport layer ETL1, and a second electrode E2.

The second light emitting element ED2 includes a first electrode E1b, a second hole injection layer HIL2, a second hole transport layer HTL2, a second light emitting layer EML2, a second electron transport layer ETL2, and a second electrode E2.

The third light emitting element ED3 includes a first electrode E1c, a third hole injection layer HIL3, a third hole transport layer HTL3, a third light emitting layer EML3, a third electron transport layer ETL3, and a second electrode E2.

A partition wall PDL may be arranged between the red light emitting region RLA, the green light emitting region GLA, and the blue light emitting region BLA. The partition wall PDL may include a first opening OP1 overlapping with the red light emitting region RLA, a second opening OP2 overlapping with the green light emitting region GLA, and a third opening OP3 overlapping with the blue light emitting region BLA.

The first opening OP1 and the first electrode E1a of the first light emitting element ED1 overlap, the second opening OP2 and the first electrode E1b of the second light emitting element ED2 overlap, and the third opening OP3 and the first electrode Elc of the third light emitting element ED3 may overlap. At least a portion of the first electrode E1a of the first light emitting element ED1, the first electrode E1b of the second light emitting element ED2, and the first electrode Elc of the third light emitting element ED3 is formed by a partition wall PDL and may be overlapped. Due to the partition wall PDL, the first electrode E1a of the first light emitting element ED1, the first electrode E1b of the second light emitting element ED2, and the first electrode E1c of the third light emitting element ED3 can be separated from each other.

The first hole injection layer HIL1 may be arranged on the first electrode E1a of the first light emitting element ED1, the second hole injection layer HIL2 may be arranged on the first electrode E1b of the second light emitting element ED2, and the third hole injection layer HIL3 may be arranged on the first electrode E1c of the third light emitting element ED3. The first hole injection layer HIL1, the second hole injection layer HIL2, and the third hole injection layer HIL3 may be spaced and/or apart (e.g., spaced apart or separated) from each other based on (by) the partition PDL. The first hole injection layer HIL1 may be arranged in the first opening OP1, the second hole injection layer HIL2 may be arranged in the second opening OP2, and the third hole injection layer HIL3 may be arranged in the third opening OP3.

Each of the first hole injection layer HIL1, the second hole injection layer HIL2, and the third hole injection layer HIL3 may be formed through an inkjet process. The first hole injection layer HIL1, the second hole injection layer HIL2, and the third hole injection layer HIL3 may include the same (substantially the same) material, but the present disclosure is not limited thereto, and the hole injection layers may include different materials.

Each of the first hole injection layer HIL1, the second hole injection layer HIL2, and the third hole injection layer HIL3 may include a hole injection material. Hole injection materials include phthalocyanine compounds such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′,4″-tris(N,N-diphenylamino)triphenylamine), 2-TNATA (4,4′,4″-tris{N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonic acid), PANI/PSS (polyaniline/poly(4-styrenesulfonate)), NPB (N,N′-di(naphthalene-I-yl)-N,N′-diphenyl-benzidine), NPD (N,N′-di(1-naphthyl)-N,N′-diphenyl-(1,1′-biphenyl)-4,4′-diamine), triphenylamine-containing polyether ketone (TPAPEK), 4-isopropyl-4′-methyldiphenyliodonium [tetrakis(pentafluorophenyl)borate], HAT-CN (dipyrazino[2,3-f: 2′,3′-h]quinoxaline-2,3,6,7,10,11-hexacarbonitrile), and/or the like.

On the first hole injection layer HIL1, the first hole transport layer HTL1 may be arranged, on the second hole injection layer HIL2, the second hole transport layer HTL2 may be arranged, and on the third hole injection layer HIL3, the third hole transport layer HTL3 may be arranged. The first hole transport layer HTL1, the second hole transport layer HTL2, and the third hole transport layer HTL3 may be spaced and/or apart (e.g., spaced apart or separated) from each other based on (by) the partition wall PDL. The first hole transport layer HTL1 may be arranged in the first opening OP1, the second hole transport layer HTL2 may be arranged in the second opening OP2, and the third hole transport layer HTL3 may be arranged in the third opening OP3.

Each of the first hole transport layer HTL1, the second hole transport layer HTL2, and the third hole transport layer HTL3 may be formed through an inkjet process. The first hole transport layer HTL1, the second hole transport layer HTL2, and the third hole transport layer HTL3 may include the same (substantially the same) material, but the present disclosure is not limited thereto, and the hole transport layers may include different materials.

Each of the first hole transport layer HTL1, the second hole transport layer HTL2, and the third hole transport layer HTL3 may include a hole transport material.

Hole transport materials can include derivatives of carbazole such as N-phenyl carbazole, polyvinyl carbazole, derivatives of fluorene, triphenylamine derivatives like TPD (N,N′-bis(3-methylphenyl)-N,N′-diphenyl-[1,1-biphenyl]-4,4′-diamine), TCTA (4,4′,4″-tris(N-carbazolyl)triphenylamine), NPB (N,N′-di(naphthalene-1-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), CzSi (9-(4-tert-butylphenyl)-3,6-bis(triphenylsilyl)-9H-carbazole), m-MTDATA (4,4′,4″-[tris(3-methylphenyl)phenylamino]triphenylamine), and/or the like.

The first light emitting layer EML1 may be arranged on the first hole transport layer HTL1, the second light emitting layer EML2 may be arranged on the second hole transport layer HTL2, and the third light emitting layer EML3 may be arranged on the third hole transport layer HTL3. The first light emitting layer EML1, the second light emitting layer EML2, and the third light emitting layer EML3 may be spaced and/or apart (e.g., spaced apart or separated) from each other based on (by) the partition wall PDL. The first emitting layer EML1 may be arranged in the first opening OP1, the second emitting layer EML2 may be arranged in the second opening OP2, and the third emitting layer EML3 may be arranged in the third opening OP3. Each of the first emitting layer EML1, the second emitting layer EML2, and the third emitting layer EML3 may be manufactured through an inkjet process.

The first light emitting layer EML1, the second light emitting layer EML2, and the third light emitting layer EML3 may be to emit light of different colors.

The first light emitting layer EML1 may be to emit red light. The first light emitting layer EML1 may include first quantum dots. The second light emitting layer EML2 may be to emit green light. The second light emitting layer EML2 may include second quantum dots.

Now, quantum dots including first quantum dots and second quantum dots will be described in more detail below.

In the present disclosure, quantum dots (hereinafter, also referred to as semiconductor nanocrystals) may include Group II-VI compounds, Group Ill-V compounds, Group IV-VI compounds, Group IV elements or compounds, Group 1-Ill-VI compounds, Group II-Ill-VI compounds, Group I-II-IV-VI compounds, and/or a (e.g., any suitable) combination thereof.

The Group II-VI compounds include binary compounds selected from the group consisting of CdSe, CdTe, ZnS, ZnSe, ZnTe, ZnO, HgS, HgSe, HgTe, MgSe, MgS, and/or a (e.g., any suitable) mixture thereof; a group made up of a tri-element compound selected from among AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) mixture thereof; and a tetraelement compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or a (e.g., any suitable) mixture thereof. The Group II-VI compound may further include a Group III metal.

The Group III-V compounds include binary compounds selected from the group consisting of GaN, GaP, GaAs, GaSb, AlN, AlP, AlAs, AlSb, InN, InP, InAs, InSb, and/or a (e.g., any suitable) mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and/or a (e.g., any suitable) mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and/or a (e.g., any suitable) mixture thereof. The Group III-V compound may further include a Group II metal (e.g., InZnP).

The Group IV-VI compounds include binary compounds selected from the group consisting of SnS, SnSe, SnTe, PbS, PbSe, PbTe, and/or a (e.g., any suitable) mixture thereof; a ternary compound selected from the group consisting of SnSeS, SnSeTe, SnSTe, PbSeS, PbSeTe, PbSTe, SnPbS, SnPbSe, SnPbTe, and/or a (e.g., any suitable) mixture thereof; and a quaternary element compound selected from the group consisting of SnPbSSe, SnPbSeTe, SnPbSTe, and/or a (e.g., any suitable) mixture thereof.

The Group IV element or compound is a monoelement compound selected from the group consisting of Si, Ge, and/or a (e.g., any suitable) combination thereof; and a binary compound selected from the group consisting of SiC, SiGe, and/or a (e.g., any suitable) combination thereof, but the present disclosure is not limited thereto.

Examples of the Group I-III-VI compounds include, but are not limited to, CuInSe₂, CuInS₂, CuInGaSe, and CuInGaS. Examples of the Group I-II-IV-VI compounds include, but are not limited to, CuZnSnSe and CuZnSnS. The Group IV element or compound is a single element selected from the group consisting of Si, Ge, and/or a (e.g., any suitable) mixture thereof; and a binary compound selected from the group consisting of SiC, SiGe, and/or a (e.g., any suitable) mixture thereof.

The Group II-III-VI compounds include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, and HgAlTe, and may be selected from the group consisting of HgInTe, MgGaS, MgAlS, MgInS, MgGaSe, MgAlSe, MglnSe, and/or a (e.g., any suitable) combination thereof, but the present disclosure is not limited thereto.

The Group I-II-IV-VI compound may be selected from among CuZnSnSe and CuZnSnS, but the present disclosure is not limited thereto.

In one or more embodiments, the quantum dots may not include (e.g., may exclude) cadmium. Quantum dots may include semiconductor nanocrystals based on Group III-V compounds including indium and phosphorus. The Group III-V compound may further include zinc. Quantum dots may include semiconductor nanocrystals based on Group II-VI compounds including chalcogen elements (e.g., sulfur, selenium, tellurium, and/or a (e.g., any suitable) combination thereof), and zinc.

In quantum dots, the above-mentioned di-element compound, tri-element compound, and/or quaternary compound may exist in the particle at a substantially uniform concentration, or may exist in the same particle with a concentration distribution partially divided into different states. Additionally, one quantum dot may have a core/shell structure around (e.g., surrounding) other quantum dots. The interface between the core and the shell may have a concentration gradient in which the concentration of elements present in the shell decreases (or increases) toward the center.

In one or more embodiments, quantum dots may have a core-shell structure including a core containing the above-described nanocrystals and a shell around (e.g., surrounding) the core. The shell of the quantum dot may serve as a protective layer to maintain semiconductor properties by preventing or reducing chemical denaturation of the core and/or as a charging layer to impart electrophoretic properties to the quantum dot. The shell may be single or multi-layered. The interface between the core and the shell may have a concentration gradient in which the concentration of elements present in the shell decreases (or increases) toward the center. Examples of the shell of the quantum dot include metal or non-metal oxides, semiconductor compounds, and/or a (e.g., any suitable) combination thereof.

For example, the oxide of the metal or non-metal may be a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, or MgAl₂O₄, CoFe₂O₄, NiFe₂O₄, CoMn₂O₄, and/or the like, but the present disclosure is not limited thereto.

In one or more embodiments, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like. However, the present disclosure is not limited thereto.

The interface between the core and the shell may have a concentration gradient in which the concentration of elements present in the shell decreases (or increases) toward the center. Additionally, the semiconductor nanocrystal may have a structure including a single semiconductor nanocrystal core and a multi-layered shell around (e.g., surrounding) it. In one or more embodiments, the multilayer shell can have two or more layers, such as 2, 3, 4, 5, or more layers. The two adjacent layers of the shell may have a single composition or different compositions. In a multilayer shell, each layer can have a composition that changes along the radius.

Quantum dots may have a full width of half maximum FWHM of the emission wavelength spectrum of about 45 nm or less, about 40 nm or less, more about 30 nm or less, and within this range, color purity or color reproducibility can be improved. Additionally, because the light emitted through these quantum dots is emitted in all directions, the optical viewing angle can be improved.

The quantum dots may have different energy band gaps between the shell material and the core material. For example, the energy band gap of the shell material may be larger than that of the core material. In one or more embodiments, the energy band gap of the shell material may be smaller than that of the core material. The quantum dots may have a multi-layered shell. In a multilayer shell, the energy band gap of the outer layer may be larger than that of the inner layer (i.e., the layer closer or closest to the core). In a multilayer shell, the energy band gap of the outer layer may be smaller than that of the inner layer.

Quantum dots can control absorption/emission wavelengths by adjusting their composition and size. The maximum emission peak wavelength of the quantum dot may range from ultraviolet to infrared wavelengths or longer.

Quantum dots may have quantum efficiency of at least about 10%, such as at least about 30%, at least about 50%, at least about 60%, at least about 70%, at least about 90%, or even at least about 100%. Quantum dots can have a relatively narrow spectrum. The quantum dots may have a full width at half maximum of the emission wavelength spectrum, for example, of about 50 nm or less, such as about 45 nm or less, about 40 nm or less, or about 30 nm or less.

The quantum dots may have a particle size of about 1 nm or more and about 100 nm or less. The size of a particle refers to the diameter of the particle or the diameter converted by assuming a spherical shape from a two-dimensional image obtained by transmission electron microscopy analysis. The quantum dots can have a size of about 1 nm to about 20 nm, for example, about 2 nm or more, about 3 nm or more, or about 4 nm or more and about 50 nm or less, about 40 nm or less, about 30 nm or less, about 20 nm or less, about 15 nm or less, for example, about 10 nm or less. In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The shape of the quantum dot is not particularly limited. For example, the shape of the quantum dot may include, but is not limited to, a sphere, polyhedron, pyramid, multipod, square, cuboid, nanotube, nanorod, nanowire, nanosheet, and/or a (e.g., any suitable) combination thereof.

Quantum dots are commercially available or can be appropriately or suitably synthesized. The particle size of quantum dots can be controlled or selected relatively freely during colloid synthesis, and the particle size can also be adjusted uniformly (e.g., substantially uniformly).

Quantum dots may include organic ligands (e.g., having hydrophobic and/or hydrophilic moieties). The organic ligand residue may be bound to the surface of the quantum dot. The organic ligand includes RCOOH, RNH₂, R₂NH, R₃N, RSH, R₃PO, R₃P, ROH, RCOOR, RPO(OH)₂, RHPOOH, R₂POOH, and/or a (e.g., any suitable) combination thereof, where each R is independently a substituted or unsubstituted C3 to C40 alkyl (e.g., C5 or more and C24 or less), a substituted or unsubstituted alkenyl, a substituted or unsubstituted aliphatic C3 to C40 hydrocarbon group, a substituted or unsubstituted C6 to C40 aryl group, a substituted or unsubstituted aromatic C6 to C40 hydrocarbon group (e.g., C6 or more and C20 or less), and/or a (e.g., any suitable) combination thereof.

Examples of the organic ligand include thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, and dipropyl amine; amines such as tributylamine, trioctylamine, and/or the like; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, trioctyl phosphine, and/or the like; phosphines such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide, or its oxide compound; diphenyl phosphine, triphenyl phosphine compounds, or their oxide compounds; C5 to C20 alkyl phosphinic acids, C5 to C20 alkyl phosphonic acids such as hexylphosphinic acid, octylphosphinic acid, dodecanephosphinic acid, tetradecanephosphinic acid, hexadecanephosphinic acid, and octadecanephosphinic acid; but the present disclosure is not limited thereto. Quantum dots may include hydrophobic organic ligands alone or in a mixture of one or more types (kinds). The hydrophobic organic ligand may not contain a photopolymerizable residue (e.g., an acrylate group, a methacrylate group, and/or the like).

The third light emitting layer EML3 may be to emit blue light. The third emitting layer EML3 may include an organic material, particularly a low-molecular organic material or a high-molecular organic material such as poly(3,4-ethylenedioxythiophene) PEDOT with a molecular weight of 10,000 or more.

Referring again to FIG. 4, the first electron transport layer ETL1 may be arranged on the first light emitting layer EML1, the second electron transport layer ETL2 may be arranged on the second light emitting layer EML2, and the third electron transport layer ETL3 may be arranged on the third light emitting layer EML3.

The first electron transport layer ETL1, the second electron transport layer ETL2, and the third electron transport layer ETL3 may be spaced and/or apart (e.g., spaced apart or separated) by the partition wall PDL. The first electron transport layer ETL1 may be arranged in the first opening OP1, the second electron transport layer ETL2 may be arranged in the second opening OP2, and the third electron transport layer ETL3 may be arranged in the third opening OP3.

The first electron transport layer ETL1, the second electron transport layer ETL2, and the third electron transport layer ETL3 may each be formed through an inkjet process. The first electron transport layer ETL1 and the second electron transport layer ETL2, according to one or more embodiments, may include the same (substantially the same) electron transport material. The third electron transport layer ETL1 may include an electron transport material different (substantially different) from the first electron transport layer ETL2 and the second electron transport layer ETL3.

The first electron transport layer ETL1 and the second electron transport layer ETL2 may include ZnMO. M may be Mg, Ca, Zr, W, Li, Ti, Y, Al, and/or a (e.g., any suitable) combination thereof.

In one or more embodiments, the third electron transport layer ETL3 may include an electron transport material and, depending on the embodiment, may include a triazine-based compound or an anthracene-based compound. However, the present disclosure is not limited to this, and the electronic transport material may include, for example, Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP(2,9-dimethyl-4,7-diphenyl-1,10-phenanthroline), Bphen (4,7-diphenyl-1,10-phenanthroline), TAZ(3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (berylliumbis(benzoquinolin-10-olate), ADN (9,10-di(naphthalene-2-yl)anthracene), TSPO1 (diphenyl(4-(triphenylsilyl)phenyl)phosphine oxide), TPM-TAZ (2,4,6-tris(3-(pyrimidin-5-yl)phenyl)-1,3,5-triazine), and/or a (e.g., any suitable) mixture thereof.

The second electrode E2 may be arranged on the first electron transport layer ETL1, the second electron transport layer ETL2, and the third electron transport layer ETL3. The second electrode E2 may be continuously arranged across (e.g., may be arranged continuously across the entirety of) the red light emitting region RLA, the green light emitting region GLA, the blue light emitting region BLA, and the non-light emitting region NLA. The second electrode E2 may receive a common voltage through a common voltage transmitter in the non-display area.

Here, the first electrodes E1a, E1b, and E1c may be an anode, which is a hole injection electrode, and the second electrode E2 may be a cathode, which is an electron injection electrode. However, the present disclosure is not necessarily limited to this, and the first electrodes E1a, E1b, and E1c may be cathodes and the second electrodes E2 may be anodes depending on the driving method of the display device.

A buffer layer BF2 may be arranged on the second electrode E2. The buffer layer BF2 may be continuously arranged across (e.g., may be arranged continuously across the entirety of) the red light emitting region RLA, the green light emitting region GLA, the blue light emitting region BLA, and the non-light emitting region NLA. The buffer layer may include lithium fluoride LiF. The buffer layer BF2 may be deposited through a spin coating process.

An encapsulation layer ENC may be arranged on the buffer layer BF2. The encapsulation layer ENC may seal the display layer by covering not only the top surface but also the side surfaces of the display layer including the light emitting elements ED1, ED2, and ED3.

Because the light emitting element is very vulnerable to moisture and/or oxygen, the encapsulation layer ENC seals the display layer and blocks the inflow of external moisture and oxygen. The encapsulation layer ENC may include a plurality of layers, and may be formed of a composite film including both an inorganic layer and an organic layer, including a first inorganic layer EIL1, an organic layer EOL, and a second inorganic layer EIL2 and may be formed of sequentially formed triple layers. That is, the light-emitting element may be highly vulnerable to moisture and oxygen. To protect it, the encapsulation layer ENC seals the display layer and blocks external moisture and/or oxygen. This encapsulation layer ENC may include or be multiple layers, forming a composite film that includes both inorganic and organic layers. Specifically, the encapsulation layer may include the first inorganic layer EIL1, the organic layer EOL, and the second inorganic layer EIL2, arranged sequentially as triple layers.

The first inorganic layer EIL1 may be a silicon oxide SiOₓ (where x is a suitable value, e.g., greater than zero and less than or equal to two). By using silicon oxide as the first inorganic layer, the first organic sub-layer PAA and the second organic sub-layer MN can be coated without spreadability if (e.g., when) coating the first inorganic layer EIL1. Because of this, a partition wall may be unnecessary between the first organic sub-layer PAA and the second organic sub-layer MN.

The second inorganic layer EIL2 may be a silicon nitride SiNₓ (where x is a suitable value, e.g., greater than zero and less than or equal to two) compound. The first inorganic layer EIL1 and the second inorganic layer EIL2 may each form one substantially continuous layer over the red light emitting region RLA, the green light emitting region GLA, and the blue light emitting region BLA.

The organic layer EOL may include a first organic sub-layer PAA and a second organic sub-layer MN.

The first organic sub-layer PAA may be continuously arranged over the first opening OP1 and the second opening OP2. The first organic sub-layer PAA and the second organic sub-layer MN may be arranged adjacent to each other without any empty space therebetween.

The first organic sub-layer PAA may overlap the first opening OP1 and the second opening OP2. The first organic sub-layer PAA may overlap the first light emitting layer EML1 and the second light emitting layer EML2.

The first organic sub-layer PAA may include polyacrylic acid. Polyacrylic acid can improve the device performance of a light emitting layer containing quantum dots. The light emitting layer containing quantum dots may use zinc metal oxide ZMO as an electron transport layer, but oxygen defects (oxygen vacancies) may occur in the zinc metal oxide ZMO. Oxygen vacancies can cause the increase of trap density of the device, and the increased trap density can reduce the electron transport rate, which can deteriorate the performance of the device. When coating polyacrylic acid, polyacrylic acid can act as a hydrogen (H) source, and hydroxyl (OH) bonds can be formed on the surface of zinc metal oxide ZMO to fill oxygen vacancies. Because polyacrylic acid is acidic, there is a risk of oxidation and reduced lifespan if (e.g., when) coated on an organic light emitting material, so it can only be coated on a light emitting layer containing quantum dots.

The second organic sub-layer MN may include a monomer. The monomer can include at least one of dodecyl methacrylate, trimethylolpropane triacrylate, or trimethylbenzoyl-diphenyl phosphine oxide, and may be a compound that includes all of these.

The second organic sub-layer MN may overlap the third opening OP3. The second organic sub-layer MN may overlap the third light emitting layer EML3.

The display device according to one or more embodiments patterns the organic layer EOL of the encapsulation layer ENC, prints polyacrylic acid on the light emitting layer containing quantum dots, and prints a monomer on the organic light emitting layer. Polyacrylic acid can improve the efficiency of the light emitting layer containing quantum dots by providing hydrogen (H) to the electron transport layer ETL, and monomer printing can prevent the lifespan of the organic light emitting layer from deteriorating (or reduce the likelihood that the organic light emitting layer will deteriorate), providing a display device with improved overall efficiency and lifespan.

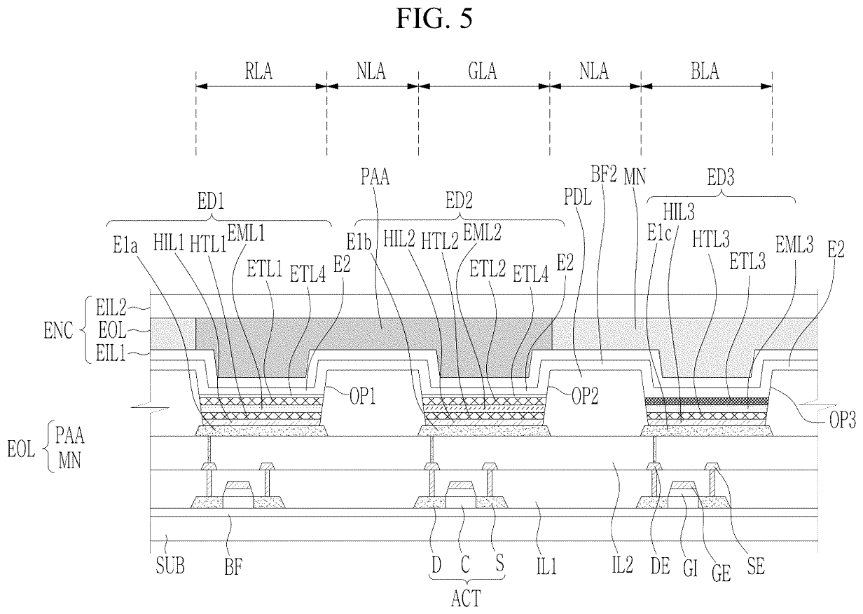

FIG. 5 is a cross-sectional view of a display device in which the first light emitting element and the second light emitting element additionally include a metal oxide layer ETL4 as an electron transport layer, according to one or more embodiments of the present disclosure.

The metal oxide layer ETL4 may include zinc oxide ZnO. The electron transport layer with a two-layer structure can efficiently inject electrons from the electrode and effectively block or reduce the flow of holes from the light emitting layer. However, as with zinc metal oxide ZMO, oxygen vacancies may occur, so by printing polyacrylic acid and supplying protons, hydroxyl (OH) bonds are formed on the surface of the metal oxide layer ETL4, thereby eliminating oxygen vacancies. As a result, the trap density of the light emitting element containing quantum dots can be reduced, thereby improving device performance.

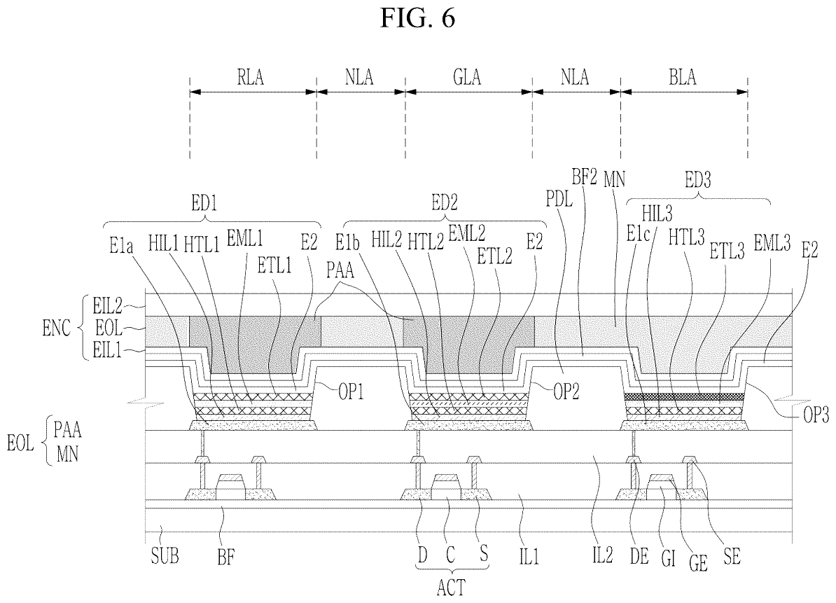

FIG. 6 is a cross-sectional view of a display device in which the first organic sub-layers are spaced and/or apart (e.g., spaced apart or separated) from each other on the first opening OP1 and the second opening OP2.

The first organic sub-layer PAA may overlap the first opening OP1 and the second opening OP2. The first organic sub-layer PAA overlapping (e.g., on or on and into, e.g., as shown in FIG. 6) the first opening OP1 and the first organic sub-layer PAA overlapping (e.g., on or on and into, e.g., as shown in FIG. 6) the second opening OP2 may be spaced and/or apart (e.g., spaced apart or separated) from each other. A second organic sub-layer MN may be arranged (e.g., laterally arranged) between the spaced and/or apart (e.g., spaced apart or separated) first organic sub-layers PAA (e.g., the second organic sub-layer MN may be arranged laterally between the spaced apart first organic sub-layers PAA). The first organic sub-layer PAA may overlap each of the red light emitting region RLA and the green light emitting region GLA, and may not be arranged in the non-light emitting region NLA.

The first light emitting layer EML1 and the second light emitting layer EML2 both contain quantum dots, and the first organic sub-layer PAA for improving the performance of the luminescent layer containing quantum dots can overlap with the first opening part OP1 and the second opening part OP2.

The display device according to one or more embodiments of FIG. 6 may be manufactured by the display device manufacturing process shown in FIG. 10 or FIG. 11.

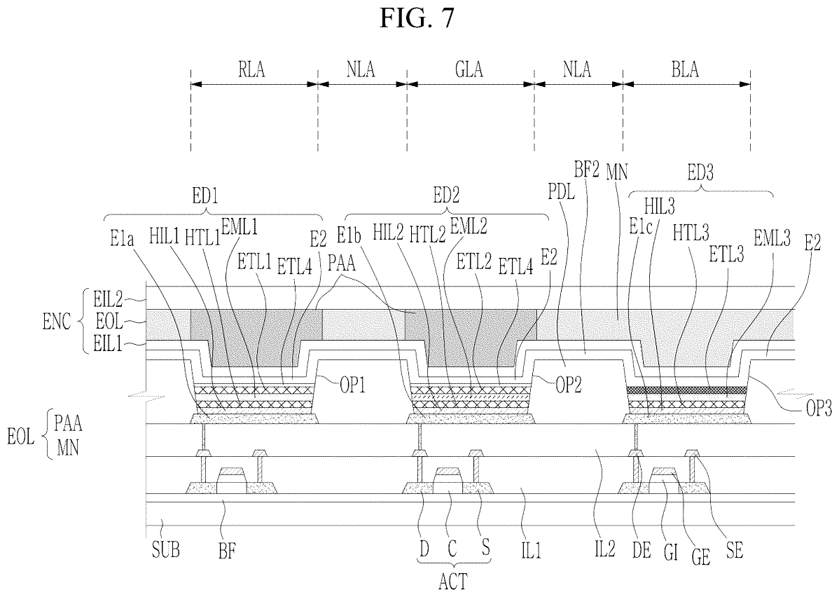

FIG. 7 is a cross-sectional view of a display device in which the first organic sub-layer is arranged separately on the first opening OP1 and the second opening OP2, and the first light emitting element ED1 and the second light emitting element ED2 additionally include a metal oxide layer ETL4 as an electron transport layer, according to one or more embodiments of the present disclosure.

The first organic sub-layer PAA may overlap the first opening OP1 and the second opening OP2. The first organic sub-layer PAA overlapping (e.g., on or on and into, e.g., as shown in FIG. 7) the first opening OP1 and the first organic sub-layer PAA overlapping (e.g., on or on and into, e.g., as shown in FIG. 7) the second opening OP2 may be spaced and/or apart (e.g., spaced apart or separated) from each other. A second organic sub-layer MN may be arranged between the spaced and/or apart (e.g., spaced apart or separated) first organic sub-layers PAA (e.g., the second organic sub-layer MN may be arranged laterally between the spaced apart first organic sub-layers PAA). The first organic sub-layer PAA may overlap each of the red light emitting region RLA and the green light emitting region GLA, and may not be arranged in the non-light emitting region NLA.

In one or more embodiments, as in FIG. 5, a metal oxide layer ETL4 may be additionally introduced into the first opening part OP1 and the second opening part OP2 containing quantum dots, forming a two-layer structure of the electron transport layer, enabling efficient injection of electrons from the electrode.

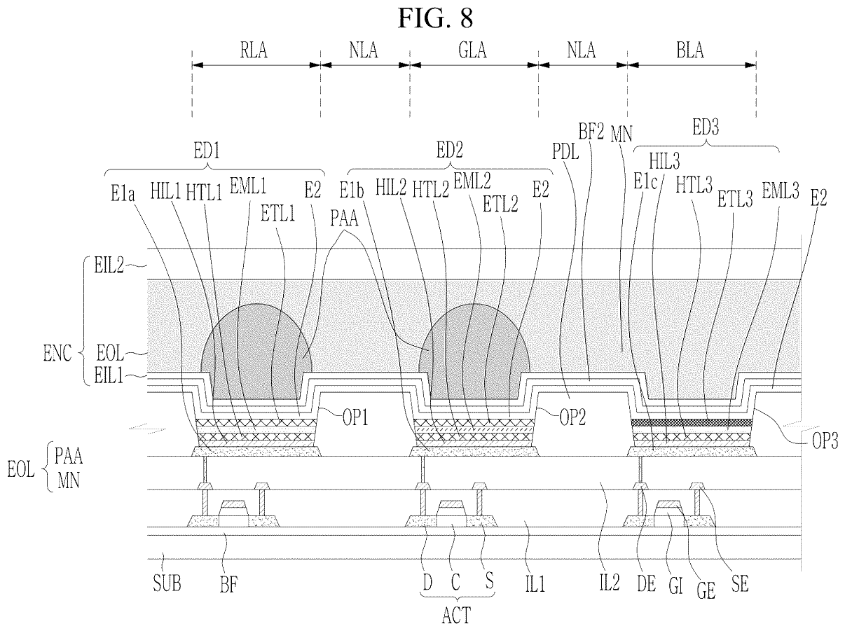

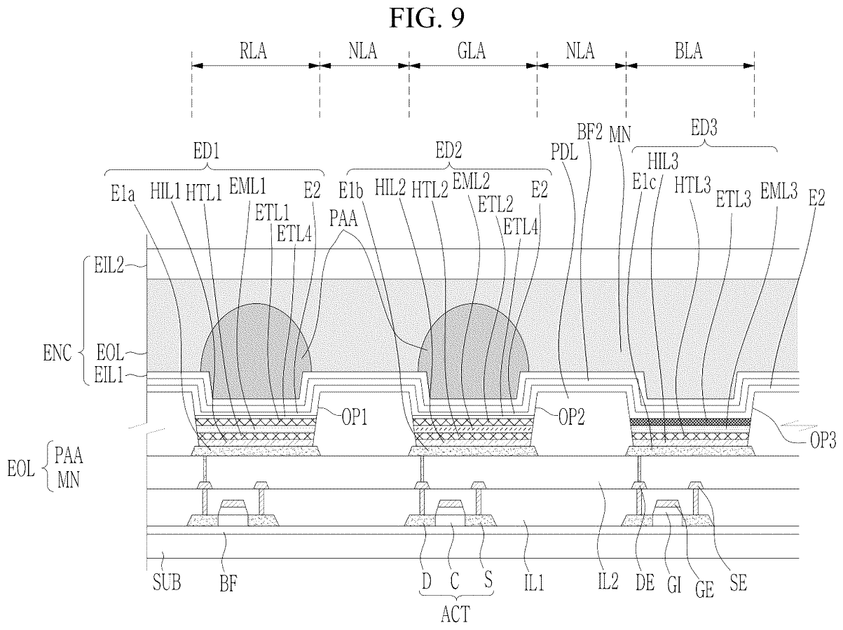

FIGS. 8 and 9 are cross-sectional views of a display device according to embodiments in which the first organic sub-layer includes a curved surface.

The surface of the first organic sub-layer PAA may include a curved surface. The first organic sub-layer PAA may have a curved surface. The first organic sub-layer PAA may have a convex structure, a hemispherical structure, or a dome shape.

The first organic sub-layer PAA is positioned separately on the first opening OP1 and the second opening OP2, and the first organic sub-layer PAA may overlap the first opening OP1 and the second opening OP2. The first organic sub-layer PAA overlapping the first opening OP1 and the first organic sub-layer PAA overlapping the second opening OP2 may be spaced apart from each other. Between the spaced first organic sub-layers PAA, a second organic sub-layer MN can be located. The second organic sub-layer MN can be positioned surrounding the first organic sub-layer PAA, and thus, the second organic sub-layer MN may be positioned on the first organic sub-layer PAA as well. The first organic sub-layer PAA may overlap with each of the red light emission area RLA and the green light emission area GLA, and it may not be located in the non-light emission area NLA.

The refractive index of the first organic sub-layer PAA may be greater than that of the second organic sub-layer MN. The refractive index difference Δn between the first organic sub-layer PAA and the second organic sub-layer layer MN may be 0.15 or more. When the first organic sub-layer PAA has curvature and the refractive index difference with the second organic sub-layer MN is 0.15 or more, lens effect may occur. The lens effect refers to the phenomenon of adjusting the path of light by utilizing the curvature of the lens and the difference in refractive index. The lens effect may increase light extraction efficiency. Light generated from the light emitting elements ED1, ED2, ED3 may be effectively emitted externally by the first organic sub-layer PAA including a curved surface, thereby improving optical efficiency.

FIG. 9 includes a metal oxide layer ETL4 within the first opening OP1 and the second opening OP2 in the structure of FIG. 8, forming a two-layer structure of the electron transport layer, thereby enabling or improving efficient electron injection from the electrode.

The display device according to FIGS. 8 and 9 can be manufactured by the manufacturing process described in FIG. 11, which will be discussed in more detail later. In the process of forming the organic layer EOL of the encapsulation layer ENC, the first organic sub-layer PAA is printed first, followed by the printing of the second organic sub-layer MN. In the step of printing the first organic sub-layer PAA (see, e.g., S7 of FIG. 11), the surface of the first organic-sub layer PAA may be formed to include a curved surface. For example, the surface of the polyacrylic acid may be formed to include a curved surface. In one or more embodiments, the first organic sub-layer PAA may also be formed in a convex structure, hemispherical structure, or dome shape. Subsequently, the second organic sub-layer MN may be printed over the entire area of the organic layer (EOL) excluding the first organic sub-layer PAA (see, e.g., S8 of FIG. 11).

Hereinafter, a method of manufacturing a display device according to one or more embodiments will be described with reference to the previously described FIGS. 4 to 9 and FIGS. 10 and 11. FIG. 10 and FIG. 11 are flowcharts of a manufacturing process of a display device according to one or more embodiments of the present disclosure. Descriptions of components that may each independently be the same or similar to those described above may not be provided.

Referring to FIGS. 4 and 10, first, a plurality of transistors may be formed on a substrate, and first electrodes E1a, E1b, and E1c are formed on a protective film (S1 in FIG. 10). On the first electrodes E1a, E1b, and E1c, a partition wall PDL having openings OP1, OP2, and OP3 exposing the first electrodes E1a, E1b, and E1c may be formed by patterning (S2 in FIG. 10).

Then, ink may be discharged into each of the openings OP1, OP2, and OP3 of the partition wall PDL to form the light emitting elements ED1, ED2, and ED3 (S3 in FIG. 10).

First, the first to third hole injection layers HIL1, HIL2, and HIL3 are formed by discharging the first ink for forming the hole injection layers HIL1, HIL2, and HIL3. Although the present embodiment describes the first ink for convenience, each of the first to third hole injection layers HIL1, HIL2, and HIL3 may include the same (substantially the same) hole injection material or may include different (substantially different) hole injection materials.

Next, the second ink for forming the first to third hole transport layers HTL1, HTL2, and HTL3 is discharged on the first to third hole injection layers HIL1, HIL2, and HIL3, respectively, to form the first to third hole transport layers HTL1, HTL2, and HTL3. Although the present embodiment describes the second ink for convenience, each of the first to third hole transport layers HTL1, HTL2, and HTL3 may include the same (substantially the same) hole transport material or different (substantially different) hole transport materials.

Next, the third ink and the fourth ink for forming the first to third light emitting layers EML1, EML2, and EML3 are discharged on the first to third hole transport layers HTL1, HTL2, and HTL3, respectively. Although the present embodiment describes the third and fourth inks for convenience, the first light emitting layer EML1 can be formed using the 3-1 ink containing the first quantum dot (red quantum dot), and the second light emitting layer EML2 can be formed using the 3-2 ink containing the second quantum dot (green quantum dot). The third light emitting layer EML3 can be formed using a fourth ink containing a blue organic material.

Then, the fifth and sixth inks for forming the first to third electron transport layers ETL1, ETL2, and ETL3 are discharged on the first to third light emitting layers EML1, EML2, and EML3, respectively. The first and second electron transport layers ETL1 and ETL2 are formed using the fifth ink. Although the fifth ink is described in the present embodiment for convenience, the first and second electron transport layers ETL2 and ETL3 may include different (substantially different) materials depending on the embodiment or may include the same (substantially the same) material (including ZnMgO, for example). A third electron transport layer ETL3 is formed using the sixth ink.

Then, the second electrode E2 is deposited (S4 in FIG. 5). The second electrode E2 may be deposited continuously over the entire surface of the substrate SUB.

A buffer layer BF2 is deposited on the second electrode E2 (S5 in FIG. 5). The buffer layer BF2 can be deposited through a spin coating process. The buffer layer BF2 may include lithium fluoride LiF.

Afterwards, an encapsulation layer ENC is formed on the buffer layer BF2.

The encapsulation layer ENC includes a first inorganic layer EIL1, an organic layer EOL, and a second inorganic layer EIL2, and may be formed sequentially in this order.

A first inorganic layer is deposited on the buffer layer BF2 (S6 in FIG. 10). The first inorganic layer EIL1 may be silicon oxide SiOₓ. The first inorganic layer EIL1 may be formed through a chemical vapor deposition process.

An organic layer EOL is formed on the first inorganic layer EIL1. The organic layer EOL includes a first organic sub-layer PAA containing polyacrylic acid and a second organic sub-layer MN containing a monomer. At this time, the first organic sub-layer PAA and the second organic sub-layer MN are concurrently (e.g., simultaneously) printed using a high-resolution inkjet printer (S7 in FIG. 10) to form an organic layer.

A second inorganic layer EIL2 is deposited on the organic layer EOL (S8 in FIG. 10). The second inorganic layer EIL2 may be a silicon nitride SiNₓ compound.

FIG. 11 is a flowchart showing another manufacturing method of a display device according to one or more embodiments. S1 in FIG. 11 to S6 in FIG. 11 may each independently be the same as in FIG. 10. When forming the encapsulation layer ENC, there is a difference in the process of forming the organic layer EOL after depositing the first inorganic layer EIL1.

In one or more embodiments, polyacrylic acid is patterned with a high-resolution inkjet printer and printed over the first opening OP1 and the second opening OP2 or spaced and/or apart (e.g., spaced apart or separated) from the first opening OP1 and the second opening OP2. Thus, the first organic sub-layer PAA is formed (S7).

Afterwards, a monomer is printed on the remaining space using a low-resolution inkjet printer to form a second organic sub-layer MN (S8).

After the organic layer EOL including the first organic sub-layer PAA and the second organic layer MN is formed, the second inorganic layer EIL2 is deposited on the organic layer EOL (S9). The second inorganic layer EIL2 may be a silicon nitride SiNₓ compound.

Using the method according to one or more embodiments of the present disclosure, the encapsulation layer can be formed more economically than the process of FIG. 10 by using a low-resolution inkjet printer.

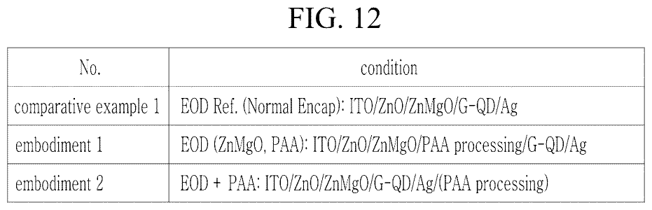

Hereinafter, improvement in performance of a light emitting element including quantum dots coated with a layer of polyacrylic acid according to one or more embodiments will be described in more detail with reference to FIGS. 12 to 15.

FIG. 12 is a table showing a comparative example and embodiments used in experiments using an EOD (electron-only device) to confirm the effect of improving trap density by including polyacrylic acid. An EOD (electron-only device) is a device that operates using only electrons and is used to measure the amount of electron injection. Comparative Example 1 shows an EOD (electron-only device) including a light emitting layer with green quantum dots, and was not treated with polyacrylic acid. Embodiment 1 shows a case in which the electron transport layer was additionally treated with polyacrylic acid in substantially the same EOD structure as Comparative Example 1. Embodiment 2 shows a case where polyacrylic acid treatment was additionally performed on the second electrode E2 in substantially the same EOD (electron only device) structure as Comparative Example 1.

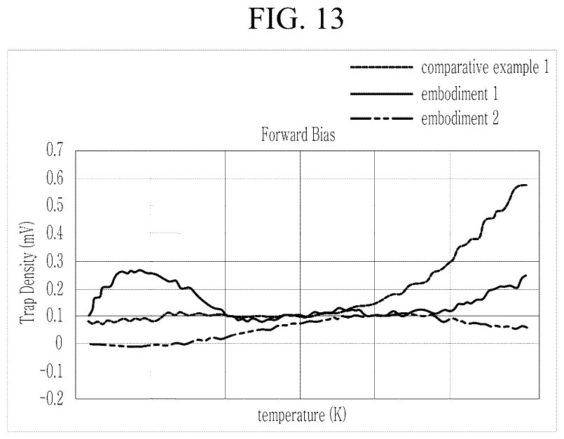

FIG. 13 is a graph of trap density measurement results for the comparative examples and embodiment of FIG. 7. In Comparative Example 1, the trap density was measured to be about 0.1 mV at 90 K, and as the temperature increased, the trap density increased, and the trap density was measured to be about 0.6 mV at 390 K. In contrast, in Embodiment 1 in which polyacrylic acid was coated on the electron transport layer, the trap density was measured to be about 0.25 mV at 390 K, confirming that the trap density was improved if (e.g., when) polyacrylic acid was treated. In one or more embodiments, Embodiment 2, in which the electrode was treated with polyacrylic acid, was also measured to have a trap density of about 0 mV at 90 K and a trap density of about 0.06 mV at 390 K, confirming that the trap density was improved compared to Comparative Example 1. According to FIG. 13, it can be seen that in the case of a display device including quantum dots, polyacrylic acid can improve trap density.

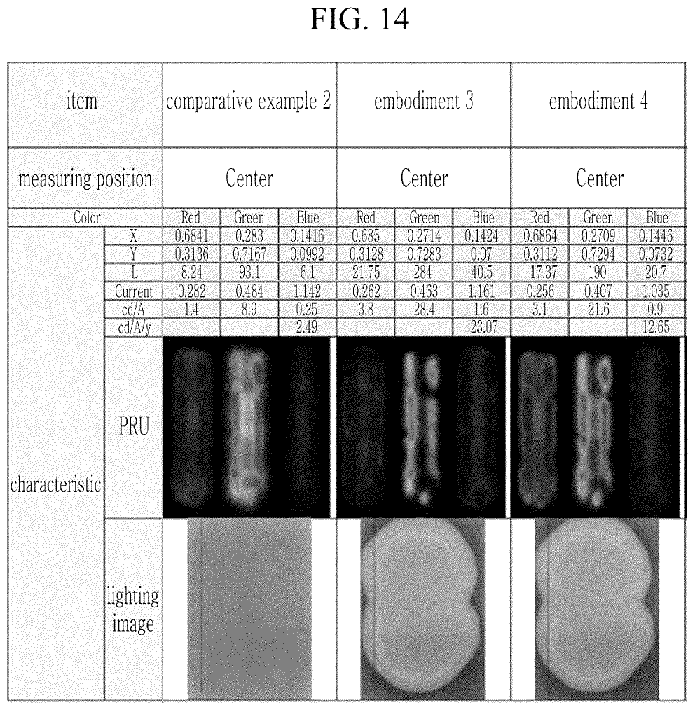

FIG. 14 is a table showing whether the efficiency of the light emitting layer containing quantum dots increases or decreases if (e.g., when) polyacrylic acid is applied to the existing encapsulating glass. The efficiency of the light emitting layer containing red, green, and blue quantum dots was measured at the center of the light emitting layer.

Comparative Example 2 shows the efficiency of the light emitting layer without polyacrylic acid treatment. The efficiency of the red light emitting layer is 1.4 cd/A/y, the efficiency of the green light emitting layer is 8.9 cd/A/y, and the efficiency of the blue light emitting layer is 0.25 cd/A/y.

Embodiment 3 is data on the efficiency of the light emitting layer if (e.g., when) polyacrylic acid is included at as much as (up to about) 0.5 wt %. In Embodiment 3, the efficiency of the red light emitting layer is 3.8 cd/A/y, the efficiency of the green light emitting layer is 28.4 cd/A/y, and the efficiency of the blue light-emitting layer is 1.6 cd/A/y compared to Comparative Example 2, so it can be confirmed that the efficiencies of the red, green, and blue light emitting layers all increased.

Embodiment 4 is data on the efficiency of the light emitting layer if (e.g., when) polyacrylic acid is included at as much as (up to about) 0.25 wt %. The efficiency of the red light emitting layer is 3.1 cd/A/y, the efficiency of the green light emitting layer is 21.6 cd/A/y, and the efficiency of the blue light emitting layer is 0.9 cd/A/y compared to Comparative Example 2, so the efficiency of the red, green, and blue light emitting layers all increased.

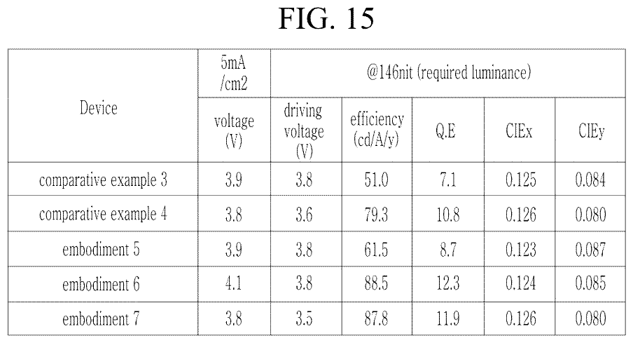

FIG. 15 shows the results of an experiment to confirm the effect if (e.g., when) polyacrylic acid was introduced into the thin film encapsulation layer rather than the encapsulation glass.

When a thin film encapsulation layer is used, the H+ ions provided by polyacrylic acid must be able to pass through the inorganic layer and reach the electron transport layer. Comparative Example 3 is the result of an experiment in which polyacrylic acid was not treated and glass encapsulation was used. Comparative Example 4 is the result of an experiment in which an encapsulated glass was used and treated with polyacrylic acid. The goal is to achieve the same efficiency or higher even if (e.g., when) polyacrylic acid is applied to the thin film encapsulation layer rather than the encapsulation glass. Therefore, in this experiment, in order to check whether the H+ ions provided by the organic layer could pass through the inorganic layer and achieve the same efficiency, the experiment was conducted by coating the bottom of the bag glass with an organic layer and coating the bottom of the organic layer with an inorganic layer. Embodiment 5 and Embodiment 6 are values for embodiments where the monomer, polyacrylic acid, and citric acid were mixed so that the mixture accounted for 1 wt % and 3 wt %, respectively. Embodiment 7 is the result of an experiment in which a separate layer was formed by coating the monomer on a mixture of polyacrylic acid and citric acid without mixing the monomer and polyacrylic acid. In Embodiment 5, the driving voltage and voltage were similar to those of Comparative Example 4, but the efficiency was 65 cd/A/y, which did not reach the target value. However, in the case of Embodiment 6, where the proportion of the polyacrylic acid mixture was increased to 3 wt %, and Embodiment 7, which formed separate layers, the efficiency was higher than the target value of Comparative Example 4, 79.3 cd/A/y, at 88.5 cd/A/y and 87.8 cd/A/y, respectively. In addition, it can be seen that the driving voltages are 3.8 V and 3.5 V, respectively, which are similar to those of Comparative Example 4. According to FIG. 10, it can be seen that even if (e.g., when) polyacrylic acid is coated on the inorganic layer, H+ ions provided by the polyacrylic acid can pass through the inorganic layer thin film and be properly transported to the electron transport layer, and the performance of the light emitting layer containing quantum dots is improved by filling the oxygen vacancies in the electron transport layer. That is, when polyacrylic acid is coated on the inorganic layer, the H+ ions from the polyacrylic acid can pass through the thin inorganic layer and reach the electron transport layer. This process fills the oxygen vacancies in the electron transport layer, thereby enhancing the performance of the quantum dot-containing light-emitting layer.

A display device according to one or more embodiments may be applied to one or more suitable electronic devices. An electronic device according to one or more embodiments may include the display device, and may further include modules or devices having additional functions other than the display device.

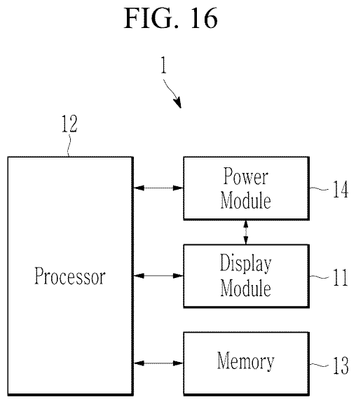

FIG. 16 is a block diagram of an electronic device according to one or more embodiments of the present disclosure. Referring to FIG. 16, the electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and/or a controller.

The memory 15 may store data information for the operation of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 1.

At least one of the components of the electronic device 1 may be included in the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 1 that are not part of the display device.

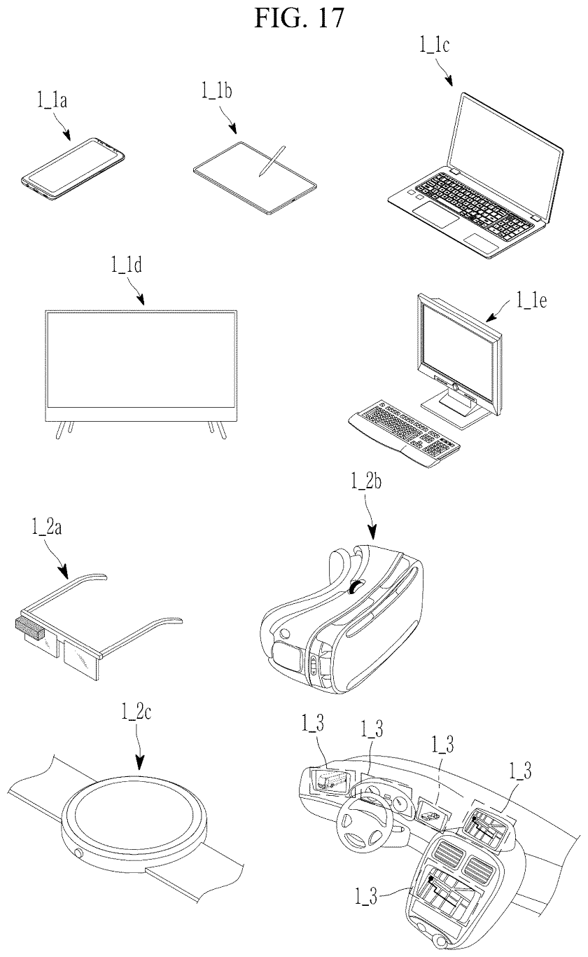

FIG. 17 shows schematic diagrams of electronic devices according to various embodiments of the present disclosure.

Referring to FIG. 17, examples of various electronic devices that may each include the display device according to embodiments of the present disclosure may include not only image display electronic devices, such as smartphones 1_1a, tablet PCs 1_1b, laptops 1_1c, TVs 1_1d, and/or desktop monitors 1_1e, but also include wearable electronic devices with display modules, such as smart glasses 1_2a, head-mounted displays 1_2b, smart watches 1_2c, as well as automotive electronic devices with display modules 1_3, such as those placed on car dashboards, center fascias, CID (Center Information Display), room mirror displays, and/or the like.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, electronic apparatus, a manufacturing device thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

### REFERENCE NUMERALS

RLA: red light emission region
GLA: green light emission region
BLA: blue light emission region
NLA: non-light emitting region
E1a, E1b, E1c: first electrode
ED1, ED2, ED3: light emitting element layer
PDL: partition wall
OP1, OP2, OP3: first opening, second opening, and third opening
HIL1, HIL2, HIL3: hole injection layer (HIL)
HTL1, HTL2, HTL3: hole transport layer (HTL)
EML1, EML2, EML3: light emitting layer
ETL1, ETL2, ETL3: electron transport layer (ETL)
ETL4: metal oxide layer
E2: second electrode
BF2: buffer layer
ENC: encapsulation layer
EIL1, EIL2: first inorganic layer, second inorganic layer
EOL: organic layer
PAA: first organic sub-layer
MN: second organic sub-layer

What is claimed is:

1. A display device comprising:
a substrate;
a transistor on the substrate;
a first electrode on the transistor;
a partition wall on the first electrode and having a first opening, a second opening, and a third opening;
a first light emitting layer in the first opening;
a second light emitting layer in the second opening;
a third light emitting layer in the third opening; and
an encapsulation layer on the first light emitting layer, the second light emitting layer, and the third light emitting layer,
wherein,
the first light emitting layer and the second light emitting layer each comprise a quantum dot,
the third light emitting layer comprises an organic material,
the encapsulation layer comprises:
a first inorganic layer,
a second inorganic layer on the first inorganic layer, and
an organic layer between the first inorganic layer and the second inorganic layer, and
wherein,
the organic layer comprises a first organic sub-layer comprising polyacrylic acid, and a second organic sub-layer comprising a monomer, and
the first organic sub-layer overlaps the first opening and the second opening and is spaced from the third opening.

2. The display device of claim 1, wherein the first organic sub-layer is continuously arranged over the first opening and the second opening.

3. The display device of claim 1, wherein the first organic sub-layer comprises two organic sub-layers spaced from each other on the first opening and the second opening.

4. The display device of claim 3, wherein the surface of the first organic sub-layer comprises a curved surface.

5. The display device of claim 4, wherein a refractive index of the first organic sub-layer is greater than a refractive index of the second organic sub-layer.

6. The display device of claim 5, wherein the difference between the refractive index of the first organic sub-layer and the refractive index of the second organic sub-layer is 0.15 or greater than 0.15.

7. The display device of claim 1, wherein a first hole injection layer, a first hole transport layer, and a first electron transport layer are in the first opening, a second hole injection layer, a second hole transport layer, and a second electron transport layer are in the second opening, and a third hole injection layer, a third hole transport layer, and a third electron transport layer are in the third opening.

8. The display device of claim 7, wherein the first light emitting layer comprises a red quantum dot, the second light emitting layer comprises a green quantum dot, and the third light emitting layer comprises a blue organic material.

9. The display device of claim 7, wherein
the first electron transport layer and the second electron transport layer comprise a compound represented by Chemical Formula 1:
ZnMO, Chemical Formula 1
wherein, in Chemical Formula 1, M is Mg, Ca, Zr, W, Li, Ti, Y, Al, or a combination thereof.

10. The display device of claim 7, wherein the first opening and the second opening further comprise a metal oxide layer.

11. The display device of claim 10, wherein the metal oxide layer comprises ZnO.

12. The display device of claim 1, wherein
the substrate comprises:
a red light emitting region to emit red light;
a green light emitting region to emit green light; and
a blue light emitting region to emit blue light; and
wherein the first inorganic layer and the second inorganic layer each form a continuous layer over the red light emitting region, the green light emitting region, and the blue light emitting region.

13. The display device of claim 1, wherein the monomer comprises at least one of dodecyl methacrylate, trimethylolpropane triacrylate, or trimethylbenzoyl diphenyl phosphine oxide.

14. The display device of claim 1, wherein the first organic sub-layer and the second organic sub-layer are adjacent to each other without any empty space therebetween.

15. A method comprising:
forming a first electrode on a substrate;
patterning a partition wall on the first electrode to form a first opening, a second opening, and a third opening;
printing a light emitting layer in the first opening, the second opening, and the third opening;
depositing a second electrode on the light emitting element;
depositing a first inorganic layer on the second electrode;
coating an organic layer on the first inorganic layer; and
depositing a second inorganic layer on the organic layer,
wherein,
the light emitting layer in each of the first opening and the second opening comprises a quantum dot,
the light emitting layer in the third opening comprises an organic light emitting material,
the organic layer comprises:
a first organic sub-layer comprising polyacrylic acid; and
a second organic sub-layer comprising a monomer,
wherein the first organic sub-layer is on the first opening and the second opening and is spaced from the third opening, and
wherein the method is a method of manufacturing a display device.

16. The method of claim 15, wherein the coating of the organic layer on the first inorganic layer comprises concurrently printing the polyacrylic acid and the monomer.

17. The method of claim 15, wherein the coating of the organic layer on the first inorganic layer comprises printing the monomer after printing the polyacrylic acid.

18. The method of claim 17, wherein printing the polyacrylic acid comprises forming the surface of the polyacrylic acid to include a curved surface.

19. An electronic device comprising:
a memory;
a processor to execute an application stored in the memory; and
a display device comprising a display module to output video information provided by the application, wherein:
the display device comprising:
a substrate;
a transistor on the substrate;
a first electrode on the transistor;
a partition wall on the first electrode and having a first opening, a second opening, and a third opening;
a first light emitting layer in the first opening;
a second light emitting layer in the second opening;
a third light emitting layer in the third opening; and
an encapsulation layer on the first light emitting layer, the second light emitting layer, and the third light emitting layer,
wherein,
the first light emitting layer and the second light emitting layer each comprise a quantum dot,
the third light emitting layer comprises an organic material,
the encapsulation layer comprises:
a first inorganic layer,
a second inorganic layer on the first inorganic layer, and
an organic layer between the first inorganic layer and the second inorganic layer, and
wherein,
the organic layer comprises a first organic sub-layer comprising polyacrylic acid, and a second organic sub-layer comprising a monomer, and
the first organic sub-layer overlaps the first opening and the second opening and is spaced from the third opening.

20. The electronic device of claim 19, wherein the surface of the first organic sub-layer includes a curved surface.
